(19) United States
(12) Patent Application Publication
(10) Pub. No.: US 2025/0227881 A1
(43) Pub. Date: Jul. 10, 2025

(54) LIQUID COOLING APPARATUS AND SERVER

(71) Applicant: SUZHOU METABRAIN INTELLIGENT TECHNOLOGY CO., LTD., Suzhou, Jiangsu (CN)

(72) Inventors: Chunhsien WU, Suzhou, Jiangsu (CN); Chang Ming KUAN, Suzhou, Jiangsu (CN); Xixi WU, Suzhou, Jiangsu (CN)

(73) Assignee: SUZHOU METABRAIN INTELLIGENT TECHNOLOGY CO., LTD., Suzhou, Jiangsu (CN)

(21) Appl. No.: 18/853,002

(22) PCT Filed: Jun. 14, 2023
(86) PCT No.: PCT/CN2023/100273

§ 371 Date: Sep. 30, 2024

(30) Foreign Application Priority Data
Dec. 5, 2022 (CN) 202211550374.1

(51) Int. Cl. H05K 7/20

(52) U.S. Cl. CPC H05K 7/20272; H05K 7/20781

(57) ABSTRACT

The present disclosure provides a liquid cooling apparatus and a server. The liquid cooling apparatus includes: a chassis; a liquid cooling unit, the liquid cooling unit is detachably snap-fitted in the chassis, one side of the liquid cooling unit is an operating side, the liquid cooling unit is provided with a cooling groove, an plugging opening of the cooling groove is located at the operating side, the plugging opening is configured for inserting a unit requiring cooling into the cooling groove or removing the unit requiring cooling from the cooling groove, a cooling channel is provided in the liquid cooling unit, and a fluid in the cooling channel is configured for cooling the unit; and a cooling pipeline, the cooling pipeline is in communication with the cooling channel, and the cooling pipeline is configured to bypass the operating side.

### CROSS-REFERENCE TO RELATED APPLICATION

The present application is a National Stage Application of PCT International Application No.: PCT/CN2023/100273 filed on Jun. 14, 2023, which claims priority to Chinese Patent Application 202211550374.1, filed in the China National Intellectual Property Administration on Dec. 5, 2022, the disclosure of which is incorporated herein by reference in its entirety.

### TECHNICAL FIELD

The present disclosure relates to the technical field of servers, and in particular, to a liquid cooling apparatus and a server.

### BACKGROUND

With the evolution of technology and the development of computer systems, the volume of servers becomes smaller and smaller, but the computation capability becomes stronger and stronger, and the density of devices becomes higher and higher. In this way, the temperature in the system increases, and the rotation speed of cooling fans needs to be higher and higher, in order to take away heat quickly. However, this comes with the downside of fans generating high-frequency noise, such that the machine room is full of noise and is not suitable for workers to work in the machine room for a long time, and the air cooling heat dissipation efficiency has been close to its limit, and gradually cannot meet the heat dissipation requirements of the servers. Therefore, the liquid cooling technology is introduced thereto, and in some key components, heat energy is taken away in a liquid cooling manner, such that the rotation speed of the fans can be reduced, noise can be further reduced, and the cooling efficiency can be improved. The liquid cooling technology is classified into two types: immersion liquid cooling and cold plate liquid cooling. The immersion liquid cooling technology has a high manufacturing cost and is inconvenient to maintain, which is not conducive to the popularization of the technology. However, the cold plate liquid cooling technology has a low cost and is gradually popularized.

At present, all liquid cooling apparatuses used on servers perform heat dissipation for central chips or other heating components on main boards. However, the liquid cooling apparatus supporting units such as a hard disk is directly fixed inside a server, and in this way, a tool needs to be used to achieve the assembly and disassembly of the liquid cooling apparatus, which is inconvenient to operate, and also reduces the opportunities of supporting other components. Furthermore, structures such as pipelines in the liquid cooling apparatus may interfere with the units when the units are assembled and disassembled, and the pipelines need to be assembled and disassembled first when the units are assembled and disassembled. In this way, the system needs to be powered off, and the operation is complicated, and existing liquid cooling apparatuses cannot support hot plugging of the units.

### SUMMARY

The present disclosure provides a liquid cooling apparatus and a server, so as to solve the problems in the related art that a liquid cooling apparatus is inconvenient to assemble and disassemble, and does not support hot plugging of units.

In order to solve the described problems, some embodiments of the present disclosure provide a liquid cooling apparatus, including: a chassis; a liquid cooling unit, the liquid cooling unit is detachably snap-fitted in the chassis, one side of the liquid cooling unit is an operating side, the liquid cooling unit is provided with a cooling groove, a plugging opening of the cooling groove is located at the operating side, the plugging opening is configured for inserting a unit requiring cooling into the cooling groove or removing the unit requiring cooling from the cooling groove, a cooling channel is provided in the liquid cooling unit, and a fluid in the cooling channels is configured for cooling the unit; and a cooling pipeline, the cooling pipeline is in communication with the cooling channel, and the cooling pipeline is configured to bypass the operating side.

In some embodiments, the liquid cooling unit is internally provided with a plurality of cooling grooves spaced apart from each other, and plugging openings of the plurality of cooling grooves are all located at the operating side.

In some embodiments, the liquid cooling unit includes a substrate and a plurality of liquid cooling plates arranged side by side on the substrate, each of the plurality of cooling grooves is formed in a region between two adjacent liquid cooling plates, and the cooling channel is distributed in the substrate and the plurality of liquid cooling plates.

In some embodiments, the substrate and the operating side are arranged opposite to each other, the cooling pipeline includes an input pipe and an output pipe, and both the input pipe and the output pipe are connected to the substrate.

In some embodiments, the liquid cooling unit is a split structure or an integrated structure, and a material of the liquid cooling unit is metal.

In some embodiments, an inner wall of the cooling groove is at least fitted with a surface of the unit having a largest area, so as to transfer a heat of the unit to the fluid in the cooling channel.

In some embodiments, the unit is provided with two opposite largest surfaces, the cooling groove is provided with two opposite cooling walls, and the two cooling walls and the two largest surfaces of the unit are fitted in one-to-one correspondence.

In some embodiments, the liquid cooling apparatus further includes a thermal pad, the thermal pad is arranged on an inner wall of the cooling groove, and in respond to an insertion of the unit into the cooling groove, the thermal pad is attached to a surface of the unit.

In some embodiments, the thermal pad is made of an elastic material, and in respond to the insertion of the unit into the cooling groove, the thermal pad is compressed.

In some embodiments, a material of the thermal pad is silica gel, and a compression ratio of the thermal pad in a thickness direction is 30%-70%.

In some embodiments, the cooling pipeline is connected to a heat exchanger by a connector, and the heat exchanger is configured to cool the fluid output from the cooling channel.

In some embodiments, the liquid cooling apparatus further includes a snap-fit structure, and the liquid cooling unit is snap-fitted with the chassis by the snap-fit structure.

In some embodiments, a bottom wall of the chassis is configured to carry the liquid cooling unit, the snap-fit structure includes an elastic snap-fit, the elastic snap-fit includes an elastic plate and a protrusion, one end of the elastic plate is fixedly connected to the chassis, the protrusion is arranged at the other end of the elastic plate, a top surface of the liquid cooling unit is provided with a groove, and the protrusion is snap-fitted with the groove.

In some embodiments, a plurality of protrusions are provided on the elastic plate side by side, the liquid cooling unit is provided with a plurality of grooves, and the plurality of protrusions are snap-fitted with the plurality of grooves in one-to-one correspondence.

In some embodiments, the elastic snap-fit further includes an actuating member, the actuating member is connected to the elastic plate, and the actuating member is configured to actuate the elastic plate.

In some embodiments, the elastic snap-fit is an integrated structure, the elastic plate is provided with a through hole, and the protrusion is provided with a guide inclined surface.

In some embodiments, the snap-fit structure further includes a snap-fit hook provided on a bottom wall of the chassis, fastening snap-fit groove is provided at a bottom of the liquid cooling unit, and the snap-fit hook is snap-fitted with the snap-fit groove.

In some embodiments, an opening direction of the snap-fit groove is oriented towards the operating side of the liquid cooling unit, a plurality of snap-fit grooves and a plurality of snap-fit hooks are provided, and the plurality of snap-fit grooves and the plurality of snap-fit hooks are arranged in one-to-one correspondence.

In some embodiments, the liquid cooling apparatus further includes a connecting back plate, the connecting back plate is fixedly connected to the chassis, and a connector on the connecting back plate is located in the cooling groove; and in respond to a location of the unit in the cooling groove, a connector on the unit is fitted with the connector on the connecting back plate.

Some other embodiments of the present disclosure provide a server, the server includes the above liquid cooling apparatus.

The technical solution of the present disclosure provides a liquid cooling apparatus, including: a chassis; a liquid cooling unit, the liquid cooling unit is detachably snap-fitted in the chassis, one side of the liquid cooling unit is an operating side, the liquid cooling unit is provided with a cooling groove, an plugging opening of the cooling groove is located at the operating side, the plugging opening is configured for inserting a unit requiring cooling into the cooling groove or removing the unit requiring cooling from the cooling groove, a cooling channel is provided in the liquid cooling unit, and a fluid in the cooling channel is configured for cooling the unit; and a cooling pipeline, the cooling pipeline is in communication with the cooling channel, and the cooling pipeline is configured to bypass the operating side. By the solution, the liquid cooling unit in the liquid cooling apparatus is connected to the chassis in a snap-fit manner, such that the liquid cooling unit may be mounted onto the chassis or be dismounted from the chassis without an aid of a tool, thereby improving operation convenience and flexibility. In addition, the plugging opening of the cooling groove in the liquid cooling apparatus is located at the operating side, and the cooling pipeline bypasses the operating side. In this way, the cooling pipeline does not hinder the operating side and does not interfere with an insertion and removal of units, and the insertion and removal of the units do not affect other structures. Therefore, hot plugging of units may be supported, facilitating operation.

The technical solution provided in the present disclosure also has the following technical effects or features:

By providing the plurality of cooling grooves spaced apart from each other in the liquid cooling unit, a plurality of units may be placed in one liquid cooling unit, the cooling channel and the cooling pipeline are shared by one liquid cooling unit, that is, the plurality of units are cooled by the same apparatus. Compared with the related art in which liquid cooling structures are provided separately for respective units, there is no need to separately provide the cooling channel and the cooling pipeline, simplifying a structure of the apparatus, improving a compactness of the apparatus, reducing costs, and facilitating assembly.

In the technical solution, the inner wall of the cooling groove is at least fitted with the surface of the unit having the largest area, so as to transfer the heat of the unit to the fluid in the cooling channel. In this way, the inner wall of the cooling groove performs heat exchange with the surface of the unit having the largest area, such that a heat exchange area is large and a heat exchange efficiency is high. Compared with the related art in which a liquid cooling structure performs heat exchange with an end surface of a unit having a smaller area, a cooling efficiency is improved.

In the technical solution, the cooling channel is distributed in both the plurality of liquid cooling plates and the substrate, and channels in different liquid cooling plates are all in communication with the channel in the substrate, such that the substrate also has functions of fluid distribution and collection.

In the technical solution, the thermal pad is provided on the inner wall of the cooling groove, and when the unit is inserted into the cooling groove, the thermal pad is attached to the surface of the unit, which may also be understood as that the thermal pad fills a gap between the inner wall of the cooling groove and the surface of the unit to ensure a sufficient contact area, and heat dissipated by the unit is transferred to the liquid cooling unit by the thermal pad, thereby ensuring a heat dissipation effect.

By arranging the elastic snap-fit, the liquid cooling unit is restricted from moving upwards, and the elastic snap-fit may restrict a position of the liquid cooling unit in a horizontal direction. When the liquid cooling unit needs to be disassembled, the elastic plate is pulled outwards, such that the elastic plate moves in a direction away from the liquid cooling unit, the elastic plate drives the protrusion to move, and the protrusion moves out of the groove, that is, the restriction of the elastic snap-fit on the liquid cooling unit is released.

By a fitting of the snap-fit hook and the snap-fit groove, a position restriction effect on the liquid cooling unit is further improved, thereby ensuring that the liquid cooling unit is fixed at a certain position, and preventing the liquid cooling unit from moving. The opening direction of the snap-fit groove is oriented towards the operating side of the liquid cooling unit. In this way, during assembly, the liquid cooling unit is pushed in a direction towards the operating side of the liquid cooling unit, and the liquid cooling unit is pushed continuously after the snap-fit groove and the snap-fit hook are aligned, such that the fitting of the snap-fit hook and the snap-fit groove may be achieved. In addition, in the pushing process, the fitting of the groove and the elastic snap-fit is achieved without using a tool, an operation is simple, and a operation convenience is greatly improved. When the liquid cooling unit needs to be disassembled, the elastic snap-fit is lifted up, and the liquid cooling unit is pulled out.

By arranging a connecting back plate, in a process of inserting a hard disk or other unit into the cooling groove, a connection between the hard disk or other unit and the connecting back plate may be achieved, thereby achieving power supply and data transmission. This arrangement also facilitates a hot plugging operation of units, does not require power-off of the apparatus, and does not affect other structures. Furthermore, the connecting back plate is located between the chassis and the liquid cooling unit, and in this way, the connecting back plate does not affect the assembly and disassembly of the liquid cooling unit.

### BRIEF DESCRIPTION OF THE DRAWINGS

The drawings, which form a part of the present disclosure, are configured for providing a further understanding of the present disclosure. The embodiments of the present disclosure and the illustrations thereof are configured for explaining the present disclosure, and do not form improper limits to the present disclosure. In the drawings:

FIG. 1 shows a three-dimensional diagram of a liquid cooling apparatus according to an embodiment of the present disclosure;

FIG. 2 shows a schematic top view of a liquid cooling apparatus according to an embodiment of the present disclosure;

FIG. 3 shows a schematic diagram of assembly between a unit requiring cooling and a liquid cooling unit in FIG. 1;

FIG. 4 shows a schematic diagram of assembly between a liquid cooling unit and a chassis in FIG. 1 at an elastic snap-fit position;

FIG. 5 shows a schematic diagram of assembly between a liquid cooling unit and a chassis in FIG. 1 at a snap-fit hook position; and

FIG. 6 shows a schematic diagram of assembly and disassembly between a liquid cooling unit and a chassis in FIG. 1.

### THE DRAWINGS INCLUDE THE FOLLOWING REFERENCE SIGNS

10. chassis;
20. liquid cooling unit; 21. operating side; 22. cooling groove; 23. cooling channel; 24. substrate; 25. liquid cooling plate; 26. groove; 27. snap-fit groove;
30. cooling pipeline; 31. input pipe; 32. output pipe;
40. thermal pad;
50. heat exchanger;
60. elastic snap-fit; 61. elastic plate; 62. protrusion; 63. actuating member;
70. snap-fit hook;
80. connecting back plate;
90. unit.

### DETAILED DESCRIPTION OF THE EMBODIMENTS

The following clearly and completely describes the technical solutions in the embodiments of the present disclosure with reference to the drawings in the embodiments of the present disclosure. Apparently, the embodiments to be described are merely some rather than all of the embodiments of the present disclosure. The following description of at least one embodiment is merely illustrative in nature and is in no way intended to limit the present disclosure and any application or use thereof. All other embodiments obtained by a person of ordinary skill in the art based on the embodiments of the present disclosure without inventive efforts shall belong to the scope of protection of the present disclosure.

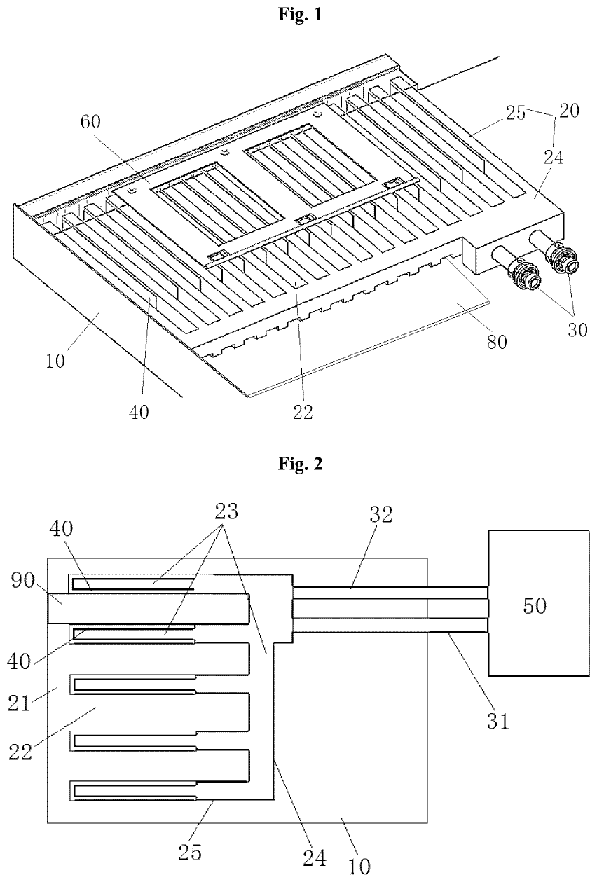

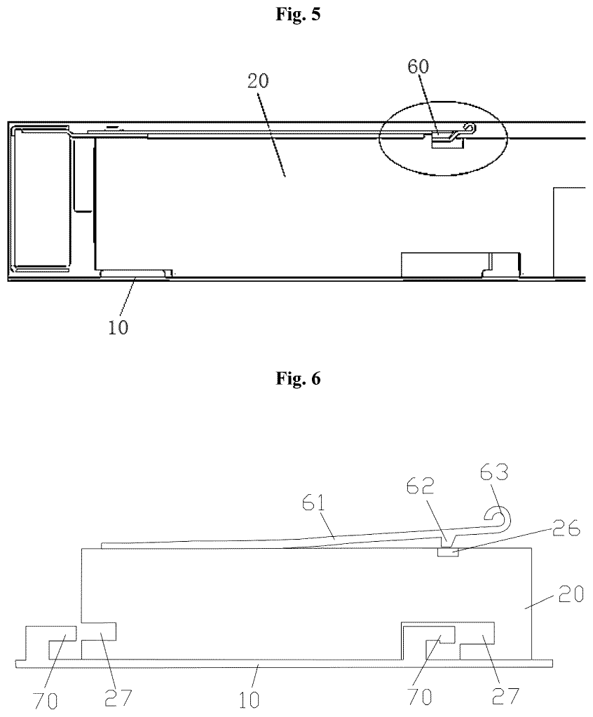

As shown in FIGS. 1-6, an embodiment of the present disclosure provides a liquid cooling apparatus, including: a chassis 10; a liquid cooling unit 20,, the liquid cooling unit 20 is detachably snap-fitted in the chassis 10, one side of the liquid cooling unit 20 is an operating side 21, the liquid cooling unit 20 is provided with a cooling groove 22, a plugging opening of the cooling groove 22 is located at the operating side 21, the plugging opening is configured for inserting a unit 90 requiring cooling into the cooling groove 22 or removing the unit 90 requiring cooling from the cooling groove 22, a cooling channel 23 is provided in the liquid cooling unit 20, and a fluid in the cooling channel 23 is configured for cooling the unit 90; and a cooling pipeline 30, the cooling pipeline 30 is in communication with the cooling channel 23, and the cooling pipeline 30 is configured to bypass the operating side 21. The unit 90 is inserted into the cooling groove 22 of the liquid cooling unit 20, such that a surface of the unit 90 is in direct contact or indirect contact with an inner wall of the cooling groove 22, a heat generated when the unit 90 operates is transferred to the fluid in the cooling channel 23 by the liquid cooling unit 20, and the heat of the unit 90 is taken away by a flowing of the fluid, thereby implementing liquid cooling heat dissipation of the unit 90. The fluid may be water or other refrigerants. The unit 90 may be a unit that generates heat when operating, such as a hard disk, a fan, an expansion card, or a processor.

In the embodiment, the liquid cooling unit 20 in the liquid cooling apparatus is connected to the chassis 10 in a snap-fit manner, such that the liquid cooling unit 20 may be mounted onto the chassis 10 or be dismounted from the chassis 10 without an aid of a tool, thereby improving operation convenience and flexibility. In addition, the plugging opening of the cooling groove 22 in the liquid cooling apparatus is located at the operating side 21, and the cooling pipeline 30 bypasses the operating side 21. In this way, the cooling pipeline 30 does not hinder the operating side 21 and does not interfere with an insertion and removal of the unit 90, and the insertion and removal of the unit 90 do not affect other structures. Therefore, hot plugging of the unit 90 may be supported, facilitating operation.

In the embodiment, the liquid cooling unit 20 is internally provided with a plurality of cooling grooves 22 spaced apart from each other, and plugging openings of the plurality of cooling grooves 22 are all located at the operating side 21. In this way, a plurality of units 90 may be placed in one liquid cooling unit 20, and the cooling channel and the cooling pipeline are shared by one liquid cooling unit 20, that is, the plurality of units 90 are cooled by the same apparatus. Compared with the related art in which liquid cooling structures are provided separately for respective units 90, there is no need to separately provide the cooling channel and the cooling pipeline, simplifying a structure of the apparatus, improving a compactness of the apparatus, reducing costs, and facilitating assembly. In addition, plugging openings of the plurality of cooling grooves 22 are all located at the operating side 21, and a person may respectively hot-plug different units 90 from the operating side 21.

The plurality of cooling grooves 22 may be in the same shape and size to fit the same units 90. In another embodiment, the plurality of cooling grooves 22 may be in different shapes or different sizes, so as to fit units 90 of different sizes or different types, which are specifically configured according to actual needs, thereby improving a universality of the apparatus.

As shown in FIGS. 1-2, the liquid cooling unit 20 includes a substrate 24 and a plurality of liquid cooling plates 25 arranged side by side on the substrate 24, each of the plurality of cooling grooves 22 is formed in a region between two adjacent liquid cooling plates 25, and the cooling channel 23 is distributed in the substrate 24 and the plurality of liquid cooling plates 25. The plurality of liquid cooling plates 25 are arranged spaced apart from each other side by side to form the plurality of cooling grooves 22 side by side, and the plurality of liquid cooling plates 25 are fixed by an arrangement of the substrate 24. Furthermore, the cooling channel is distributed in both the plurality of liquid cooling plates 25 and the substrate 24, and channels in different liquid cooling plates 25 are all in communication with channels in the substrate 24, such that the substrate 24 also has functions of fluid distribution and collection. With such a structure, the liquid cooling unit 20 just needs one set of the cooling pipeline 30 to implement fluid delivery, and there is no need to separately provide pipelines for respective liquid cooling plates 25. Compared with the related art in which pipelines are provided separately for respective liquid cooling plates, the present disclosure greatly simplifies the pipeline structure, and bypasses or reduces interference of pipelines on other structures. In addition, a reduction of the pipelines simplifies the structure, reduces a possibility of leakage, and reduces a cost of the apparatus. The assembly efficiency is further improved with the reduction of the pipelines.

The cooling pipelines 30 in the embodiment may be connected to the plurality of liquid cooling plates 25, or to the substrate 24. In an embodiment, the substrate 24 and the operating side 21 are provided opposite to each other, the cooling pipeline 30 includes an input pipe 31 and an output pipe 32, and both the input pipe 31 and the output pipe 32 are connected to the substrate 24. In this way, the cooling pipeline 30 is located at a position away from the operating side 21, and does not interfere with a person and a structure located at the operating side 21. The input pipe 31 is configured for delivering a fluid into the cooling channel 23, and the fluid in the cooling channel 23 absorbs a heat of the unit 90 and then is output from the output pipe 32. A continuous flow of the fluid ensures a cooling effect on the unit 90.

In order to further ensure the cooling effect, a delivery speed or flow rate of the fluid may be adjusted according to needs. For example, in a case that a temperature of the unit 90 is relatively high and rapid heat dissipation is required, the flow rate of the fluid is increased, thereby increasing a cooling speed. In the case that the temperature of the unit 90 is not too high, the flow rate of the fluid is decreased. In this way, a purpose of energy saving may also be achieved while ensuring the cooling effect. A temperature sensor may also be provided in the embodiment, the temperature sensor measures the temperature of the unit 90 or the fluid, and the delivery of the fluid is controlled according to the measured temperature.

The liquid cooling unit 20 is a split structure or an integrated structure, which is specifically selected according to technological requirements. A material of the liquid cooling unit 20 is metal, such as stainless steel, aluminum alloy, and copper alloy. The metal material has good thermal conductivity, and may improve a cooling efficiency.

In the embodiment, the inner wall of the cooling groove 22 is at least fitted with the surface of the unit 90 having a largest area, so as to transfer a heat of the unit 90 to the fluid in the cooling channel 23. In this way, the inner wall of the cooling groove 22 performs a heat exchange with the surface of the unit 90 having the largest area, such that a heat exchange area is large and a heat exchange efficiency is high. Compared with the related art in which a liquid cooling structure performs heat exchange with an end surface of a unit having a smaller area, the cooling efficiency is improved.

In an embodiment, the unit 90 is provided with two opposite largest surfaces, the cooling groove 22 is provided with two opposite cooling walls, and the two cooling walls and the two largest surfaces of the unit 90 are fitted in one-to-one correspondence. That is, the two cooling walls of the cooling groove 22 are fitted with the two largest surfaces of the unit 90, thereby further improving the cooling effect on the unit 90.

As shown in FIGS. 1-3, the liquid cooling apparatus further includes a thermal pad 40, the thermal pad 40 is arranged on the inner wall of the cooling groove 22, and when the unit 90 is inserted into the cooling groove 22, the thermal pad 40 is attached to the surface of the unit 90. Due to machining and assembly errors, after the unit 90 is inserted into the cooling groove 22, it is difficult to ensure that the surface of the unit 90 may be well attached to the inner wall of the cooling groove 22, a gap may exist between the two, and the gap affects heat transfer. Therefore, in the embodiment, a thermal pad 40 is arranged on the inner wall of the cooling groove 22, and when the unit 90 is inserted into the cooling groove 22, the thermal pad 40 is attached to the surface of the unit 90, which may also be understood as that the thermal pad 40 fills a gap between the inner wall of the cooling groove 22 and the surface of the unit 90 to ensure a sufficient contact area, and heat dissipated by the unit 90 is transferred to the liquid cooling unit 20 by the thermal pad 40, thereby ensuring a heat dissipation effect.

The thermal pad 40 is made of an elastic material, and when the unit 90 is inserted into the cooling groove 22, the thermal pad 40 is compressed. The thermal pad 40 is configured to be made of the elastic material, and n initial thickness of the thermal pad 40 is greater than a gap between the inner wall of the cooling groove 22 and the surface of the unit 90. In this way, after the unit 90 is inserted, the compressed thermal pad 40 fills the gap between the inner wall of the cooling groove 22 and the surface of the unit 90, thereby ensuring a surface-to-surface contact, further improving a heat dissipation effect. In addition, the thermal pad 40 also has a cushioning and vibration damping effect on the unit 90, and protects the unit 90 when the apparatus is impacted by an external force.

In an embodiment, a material of the thermal pad 40 is silica gel, and a compression ratio of the thermal pad 40 in a thickness direction is 30%-70%. The silica gel material has a high elasticity and good thermal conductivity, which ensures sufficient contact with the unit 90. In another embodiment, the thermal pad 40 may also be configured to be made of other materials as required.

As shown in FIGS. 1-2, the cooling pipeline 30 is connected to a heat exchanger 50 by a connector, and the heat exchanger 50 is configured to cool the fluid output from the cooling channel 23. After the heat exchanger 50 cools the fluid, the cooled fluid is delivered to the liquid cooling unit 20, thereby achieving a circulating flow of the fluid. The heat exchanger 50 includes a delivery pump and a heat dissipation structure. The heat dissipation structure may be a heat radiator including a plurality of fins. The fluid is delivered to the heat radiator, and the fluid in the heat radiator is cooled by air cooling. In another embodiment, the heat exchanger 50 may also be other heat dissipation structures.

In the embodiment, the liquid cooling apparatus further includes a snap-fit structure, and the liquid cooling unit 20 is snap-fitted with the chassis 10 by the snap-fit structure. The snap-fit structure may be a separate structure, and may also be a structure arranged on the chassis 10 or a structure arranged on the liquid cooling unit 20, as long as a reliable connection between the chassis 10 and the liquid cooling unit 20 is ensured and assembly and disassembly are convenient.

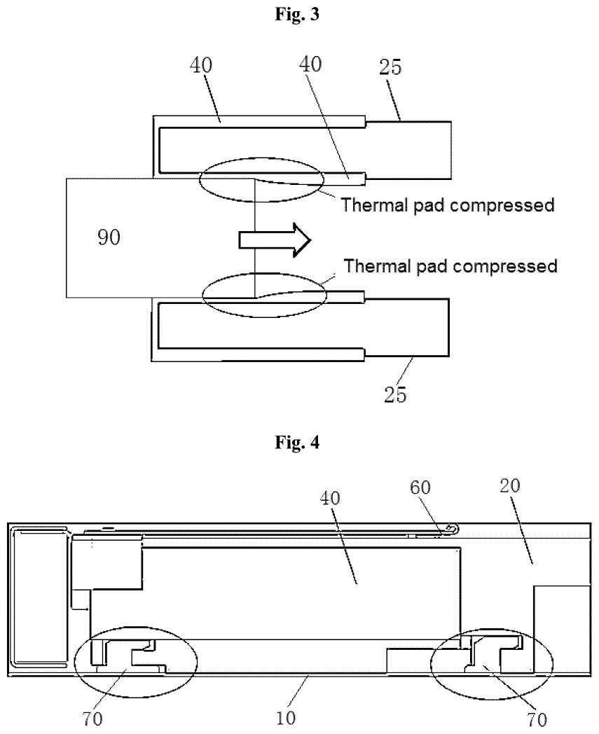

As shown in FIGS. 3-6, a bottom wall of the chassis 10 is configured to carry the liquid cooling unit 20, the snap-fit structure includes an elastic snap-fit 60, the elastic snap-fit 60 includes an elastic plate 61 and a protrusion 62, one end of the elastic plate 61 is fixedly connected to the chassis 10, the protrusion 62 are arranged at the other end of the elastic plate 61, a top surface of the liquid cooling unit 20 is provided with a groove 26, and the protrusion 62 is snap-fitted with the groove 26. In this way, a position restriction of the liquid cooling unit 20 is achieved by a fitting of the elastic snap-fit 60 and the groove 26. In an embodiment, the bottom wall of the chassis 10 restricts downward movement of the liquid cooling unit 20, the elastic snap-fit 60 restricts upward movement of the liquid cooling unit 20, and the elastic snap-fit 60 may restrict a position of the liquid cooling unit 20 in a horizontal direction. When the liquid cooling unit 20 needs to be disassembled, the elastic plate 61 is pulled outwards, such that the elastic plate 61 moves in a direction away from the liquid cooling unit 20, the elastic plate 61 drives the protrusion 62 to move, and the protrusion 62 moves out of the groove 26, that is, the restriction of the elastic snap-fit 60 on the liquid cooling unit 20 is released.

As shown in FIG. 1, a plurality of protrusions 62 are provided on the elastic plate 61 side by side, the liquid cooling unit 20 is provided with a plurality of grooves 26, and the plurality of protrusions 62 are snap-fitted with the plurality of grooves 26 in one-to-one correspondence. The position of the liquid cooling unit 20 may be restricted at different positions by a fitting of the plurality of protrusions 62 and the plurality of grooves 26, thereby improving a connection reliability. A specific number and distribution positions of the protrusions 62 and the grooves 26 may be determined according to actual needs.

In order to facilitate operation, the elastic snap-fit 60 further includes an actuating member 63, the actuating member 63 is connected to the elastic plate 61, and the actuating member 63 is configured to actuate the elastic plate 61. When operating, a person actuates or pulls the actuating member 63 to drive the elastic plate 61, thereby improving a convenience. The actuating member 63 is arranged at an end away from a connection between the elastic plate 61 and the chassis 10, thereby spending less effort.

In the embodiment, the elastic snap-fit 60 may be provided as an integrated structure, thereby facilitating machining and saving costs. For example, the elastic snap-fit 60 is a sheet metal structure formed by stamping and bending. The elastic plate 61 is provided with a through hole, thereby avoiding difficulty in elastic deformation due to large size of the elastic plate 61. The protrusion 62 is provided with a guide inclined surface. The guide inclined surface is inclined relative to a direction in which the liquid cooling unit 20 is mounted and taken out. In this way, after the protrusion 62 contacts the liquid cooling unit 20 during mounting, the elastic plate 61 is easily deformed under an action of the guide inclined surface, thereby preventing the protrusion 62 from hindering a movement of the liquid cooling unit 20.

As shown in FIG. 4 and FIG. 6, the snap-fit structure further includes a snap-fit hook 70 provided on a bottom wall of the chassis 10, a snap-fit groove 27 is provided at a bottom of the liquid cooling unit 20, and the snap-fit hook 70 is snap-fitted with the snap-fit groove 27. By a fitting of the snap-fit hook 70 and the snap-fit groove 27, the position restriction effect on the liquid cooling unit 20 is further improved, thereby ensuring that the liquid cooling unit 20 is fixed at a certain position, and preventing the liquid cooling unit 20 from moving.

In FIG. 6, an opening direction of the snap-fit groove 27 is oriented towards the operating side 21 of the liquid cooling unit 20. In this way, during assembly, the liquid cooling unit 20 is pushed in a direction towards the operating side 21 of the liquid cooling unit 20, and the liquid cooling unit is pushed continuously after the snap-fit groove 27 and the snap-fit hook 70 are aligned, such that the fitting of the snap-fit hook 70 and the snap-fit groove 27 may be achieved. In addition, in the pushing process, the fitting of the groove 26 and the elastic snap-fit 60 is achieved without using a tool, the operation is simple, and the operation convenience is greatly improved. When the liquid cooling unit 20 needs to be disassembled, the elastic snap-fit 60 is lifted up, and the liquid cooling unit 20 is pulled out.

A plurality of snap-fit grooves 27 and a plurality of snap-fit hooks 70 are provided, and the plurality of snap-fit grooves 27 and the plurality of snap-fit hooks 70 are arranged in one-to-one correspondence. By the fitting of the plurality of snap-fit grooves 27 and the plurality of snap-fit hooks 70, the position of the liquid cooling unit 20 may be restricted at different positions at the bottom of the liquid cooling unit 20, thereby ensuring that the liquid cooling unit 20 is reliably connected to the chassis 10.

In the embodiment, the liquid cooling apparatus further includes a connecting back plate 80, the connecting back plate 80 is fixedly connected to the chassis 10, and a connector on the connecting back plate 80 is located in the cooling groove 22; and when a hard disk or other unit 90 is located in the cooling groove 22, a connector on the unit 90 is fitted with the connector on the connecting back plate 80. By the described arrangement, in a process of inserting a hard disk or other unit 90 into the cooling groove 22, a connection between the hard disk or other unit 90 and the connecting back plate 80 may be achieved, thereby achieving power supply and data transmission. The arrangement also facilitates a hot plugging operation of the unit 90, does not require power-off of the apparatus, and does not affect other structures. The connecting back plate 80 is fixedly connected to the chassis 10, for example, by welding or by using a fastening member, and the connecting back plate 80 is located between the chassis 10 and the liquid cooling unit 20, and in this way, the connecting back plate 80 does not affect the assembly and disassembly of the liquid cooling unit 20.

In an embodiment, a front side of the chassis 10 is provided with a front panel, and the front panel is provided with an opening for bypassing the plugging opening of the cooling groove 22. In this way, a person at the front panel side may insert or remove the unit 90 from the opening on the front panel. After the unit 90 is inserted into the cooling groove 22, in order to prevent the unit 90 from escaping, a locking structure may be provided on the front panel. The locking structure has a locking state and an unlocking state. When the locking structure is in the locking state, the locking structure restricts the position of the unit 90 so as to prevent the unit 90 from being removed from the cooling groove 22. When the unit 90 needs to be disassembled, the locking structure is adjusted to be in the unlocking state. In this way, the locking structure bypasses the unit 90, and the unit 90 may be removed from the cooling groove 22.

Another embodiment of the present disclosure further provides a server. The server includes the above liquid cooling apparatus. In the embodiment, the liquid cooling unit 20 in the liquid cooling apparatus is connected to the chassis 10 in a snap-fit manner, such that the liquid cooling unit 20 may be mounted onto the chassis 10 or be dismounted from the chassis 10 without an aid of a tool, thereby improving operation convenience and flexibility. In addition, the plugging opening of the cooling groove 22 in the liquid cooling apparatus is located at the operating side 21, and the cooling pipeline 30 bypasses the operating side 21. In this way, the cooling pipeline 30 does not hinder the operating side 21 and does not interfere with the insertion and removal of a unit 90, and the insertion and removal of the unit 90 do not affect other structures. Therefore, hot plugging of the unit 90 may be supported, facilitating operation.

The foregoing descriptions are merely specific embodiments of the present disclosure, and are not intended to limit the present disclosure. For those skilled in the art, the present disclosure may have various modifications and variations. Any modifications, equivalent replacements, improvements and the like made within the spirit and principle of the present disclosure shall belong to the scope of protection of the present disclosure.

It should be noted that the terminology used herein is for the purpose of describing particular embodiments only and is not intended to limit the exemplary embodiments in accordance with the present disclosure. As used herein, the singular form is intended to include the plural form as well, unless the context clearly indicates otherwise, and further it should be understood that the terms “contain” and/or “include” when used in this specification, specify the presence of features, steps, operations, devices, components, and/or combinations thereof.

The relative arrangement of components and steps, numerical expressions and numerical values set forth in these embodiments do not limit the scope of the present disclosure unless specifically stated otherwise. Meanwhile, it should be understood that, for the convenience of description, the dimensions of the parts shown in the drawings are not drawn according to the actual proportional relationship. Techniques, methods, and devices known to those of ordinary skill in the relevant art may not be discussed in detail, but should be considered as a part of the granted specification, where appropriate. In all examples shown and discussed herein, any specific values should be construed as exemplary only and not as limiting. Therefore, other examples of the specific embodiments may have different values. It should be noted that similar numerals and letters represent similar items in the following drawings, and thus, once an item is defined in a figure, it does not need to be further discussed in subsequent figures.

In the description of the present disclosure, it should be understood that orientation or position relationships indicated by orientation words such as “front, rear, upper, lower, left and right”, “lateral, vertical, perpendicular and horizontal”, and “top and bottom” are generally orientation or position relationships based on those illustrated in the drawings, which are only used for facilitating description of the present disclosure and simplifying the description. If not described to the contrary, these orientation words do not indicate or imply that the apparatus or element referred to must have a specific orientation or be constructed and operated in a specific orientation, and therefore cannot be construed as limitations to the scope of protection of the present disclosure. The orientation words “inside and outside” refer to the inside and outside relative to the outline of each component itself.

Spatially relative terms, such as “over”, “above”, “on the upper surface”, “on”, and the like, may be used herein for ease of description to describe spatial positional relationships of one device or feature with other devices or features as illustrated in the drawings. It should be understood that the spatially relative terms are intended to encompass different orientations in use or operation in addition to the orientation of the device depicted in the drawings. For example, if the devices in the drawings are inverted, devices described as “above other devices or structures” or “over other devices or structures” would then be positioned as “under other devices or structures” or “beneath other devices or structures”. Accordingly, the exemplary term “above” may encompass two orientations including “above” and “under”. The device may be positioned in various other ways as well (rotated 90 degrees or at other orientations), and the spatially relative descriptions used herein are to be construed accordingly.

In addition, it should be noted that, terms such as “first” and “second” are used to define parts only for the convenience of distinguishing corresponding parts, and if no other statement is made, the described terms do not have a special meaning, and therefore cannot be construed as limitations to the scope of protection of the present disclosure.

1. A liquid cooling apparatus, comprising:
a chassis;
a liquid cooling unit, the liquid cooling unit is detachably snap-fitted in the chassis, one side of the liquid cooling unit is an operating side, the liquid cooling unit is provided with a cooling groove, a plugging opening of the cooling groove is located at the operating side, the plugging opening is configured for inserting a unit requiring cooling into the cooling groove or removing the unit requiring cooling from the cooling groove, a cooling channel is provided in the liquid cooling unit, and a fluid in the cooling channel is configured for cooling the unit; and
a cooling pipeline, the cooling pipeline is in communication with the cooling channel, and the cooling pipeline is configured to bypass the operating side.

2. The liquid cooling apparatus according to claim 1, wherein the liquid cooling unit is internally provided with a plurality of cooling grooves spaced apart from each other, and plugging openings of the plurality of cooling grooves are all located at the operating side.

3. The liquid cooling apparatus according to claim 2, wherein the liquid cooling unit comprises a substrate and a plurality of liquid cooling plates arranged side by side on the substrate, each of the plurality of cooling grooves is formed in a region between two adjacent liquid cooling plates, and the cooling channel is distributed in the substrate and the plurality of liquid cooling plates.

4. The liquid cooling apparatus according to claim 3, wherein the substrate and the operating side are arranged opposite to each other, the cooling pipeline comprises an input pipe and an output pipe, and both the input pipe and the output pipe are connected to the substrate.

5. The liquid cooling apparatus according to claim 3, wherein the liquid cooling unit is a split structure or an integrated structure, and a material of the liquid cooling unit is metal.

6. The liquid cooling apparatus according to claim 1, wherein an inner wall of the cooling groove is at least fitted with a surface of the unit having a largest area, so as to transfer a heat of the unit to the fluid in the cooling channel.

7. The liquid cooling apparatus according to claim 6, wherein the unit is provided with two opposite largest surfaces, the cooling groove is provided with two opposite cooling walls, and the two cooling walls and the two largest surfaces of the unit are fitted in one-to-one correspondence.

8. The liquid cooling apparatus according to claim 1, wherein the liquid cooling apparatus further comprises a thermal pad, the thermal pad is arranged on an inner wall of the cooling groove, and in respond to an insertion of the unit into the cooling groove, the thermal pad is attached to a surface of the unit.

9. The liquid cooling apparatus according to claim 8, wherein the thermal pad is made of an elastic material, and in respond to the insertion of the unit into the cooling groove, the thermal pad is compressed.

10. The liquid cooling apparatus according to claim 9, wherein a material of the thermal pad is silica gel, and a compression ratio of the thermal pad in a thickness direction is 30% %.

11. The liquid cooling apparatus according to claim 1, wherein the cooling pipeline is connected to a heat exchanger by a connector, and the heat exchanger is configured to cool the fluid output from the cooling channel.

12. The liquid cooling apparatus according to claim 1, wherein the liquid cooling apparatus further comprises a snap-fit structure, and the liquid cooling unit is snap-fitted with the chassis by the snap-fit structure.

13. The liquid cooling apparatus according to claim 12, wherein a bottom wall of the chassis is configured to carry the liquid cooling unit, the snap-fit structure comprises an elastic snap-fit, the elastic snap-fit comprises an elastic plate and a protrusion, one end of the elastic plate is fixedly connected to the chassis, the protrusion is arranged at the other end of the elastic plate, a top surface of the liquid cooling unit is provided with a groove, and the protrusion is snap-fitted into the groove.

14. The liquid cooling apparatus according to claim 13, wherein a plurality of protrusions are provided on the elastic plate side by side, the liquid cooling unit is provided with a plurality of grooves, and the plurality of protrusions are snap-fitted with the plurality of grooves in one-to-one correspondence.

15. The liquid cooling apparatus according to claim 13, wherein the elastic snap-fit further comprises an actuating member, the actuating member is connected to the elastic plate, and the actuating member is configured to actuate the elastic plate.

16. The liquid cooling apparatus according to claim 13, wherein the elastic snap-fit is an integrated structure, the elastic plate is provided with a through hole, and the protrusion is provided with a guide inclined surface.

17. The liquid cooling apparatus according to claim 13, wherein the snap-fit structure further comprises a snap-fit hook provided on a bottom wall of the chassis, a snap-fit groove is provided at a bottom of the liquid cooling unit, and the snap-fit hook is snap-fitted with the snap-fit groove.

18. The liquid cooling apparatus according to claim 17, wherein an opening direction of the snap-fit groove is oriented towards the operating side of the liquid cooling unit, a plurality of snap-fit grooves and a plurality of snap-fit hooks are provided, and the plurality of snap-fit grooves and the plurality of snap-fit hooks are arranged in one-to-one correspondence.

19. The liquid cooling apparatus according to claim 1, wherein the liquid cooling apparatus further comprises a connecting back plate, the connecting back plate is fixedly connected to the chassis, and a connector on the connecting back plate is located in the cooling groove; and in respond to a location of the unit in the cooling groove, a connector on the unit is fitted with the connector on the connecting back plate.

20. A server, comprising the liquid cooling apparatus according to claim 1.
